(19) United States
(12) Patent Application Publication
(10) Pub. No.: US 2020/0006170 A1
(43) Pub. Date: Jan. 2, 2020

(54) SEMICONDUCTOR MODULE

(71) Applicant: Taiyo Yuden Co., Ltd., Tokyo (JP)

(72) Inventors: Takashi NUNOKAWA, Tokyo (JP); Yuichi SASAJIMA, Tokyo (JP); Takayuki TAKANO, Tokyo (JP)

(21) Appl. No.: 16/456,342

(22) Filed: Jun. 28, 2019

(30) Foreign Application Priority Data
Jun. 29, 2018 (JP) 2018-124611

(51) Int. Cl. H01L 23/18; H01L 25/18; H01L 25/16; H01L 23/498; H01L 23/31

(52) U.S. Cl. CPC H01L 23/18; H01L 25/18; H01L 21/565; H01L 23/49838; H01L 23/3107; H01L 25/16

(57) ABSTRACT

A semiconductor module includes: a dielectric film that has a first surface and a second surface opposed to the first surface; a plurality of circuit parts mounted on the first surface; an electrode layer that is disposed on the second surface and includes a plurality of electrode portions to be electrically connected to the plurality of circuit parts, at least a part of the plurality of electrode portions including a base that is long in one axis direction; a rigid member that is disposed on the first surface, includes, at least one shaft portion, and faces the base with the dielectric layer sandwiched therebetween, the at least one shaft axis extending along the one axis direction; and a sealing layer that is provided on the first surface and covers the plurality of circuit parts and the rigid member.

### CROSS-REFERENCE TO RELATED APPLICATION

This application claims the benefit of Japanese Application No. 2018-124611, filed Jun. 29, 2018, which is hereby incorporated by reference in its entirety.

### BACKGROUND

The present disclosure relates to a semiconductor module in which a circuit part and an electrode layer are respectively disposed on one surface of a dielectric layer and the other surface.

In recent years, a surface mount integrated power module called POL (Power Over Lay) has been known (see, for example, Japanese Patent Application Laid-open No. 2014-27272). A semiconductor module of this type typically includes a dielectric film such as polyimide, a circuit part such as a power semiconductor device and a passive part mounted on one surface of the dielectric film, an electrode layer disposed on the other surface of the dielectric film, a sealing layer that covers the circuit part, and the like.

In accordance with the semiconductor module, the circuit part is electrically connected to the electrode layer via the dielectric film, and thus, it is possible to realize a power semiconductor module that achieves high integration of parts and shortening of the wiring length and that can be thinner and miniaturized while securing an insulation withstand voltage. Further, the design freedom of the electrode shape is high, and it is possible to form the electrode terminal in the power semiconductor device that controls passage of a large current into an arbitrary shape and size.

### SUMMARY

However, if the area of the electrode terminal is increased in order to cope with the large current, a warp occurs when forming the sealing layer in such a way that a part of the electrode terminal protrudes outward in some cases. That is, when forming the sealing layer by a compression molding method or a transfer molding method, the mold pressure of a resin from one surface of the dielectric film to the other surface locally deforms an electrode layer, particularly, terminal region having a relatively large area. For this reason, there is a problem that the flatness of the electrode layer is reduced and the height varies in accordance with the position of the electrode layer, which reduces the mounting reliability on the substrate is reduced.

In view of the circumstances as described above, it is desirable to provide a semiconductor module capable of inhibiting an electrode layer from being deformed.

In accordance with an embodiment of the present disclosure, there is provided a semiconductor module, including: a dielectric film; a plurality of circuit parts; an electrode layer; a rigid member; and a sealing layer.

The dielectric film has a first surface and a second surface opposed to the first surface.

The plurality of circuit parts is mounted on the first surface.

An electrode layer is disposed on the second surface and includes a plurality of electrode portions to be electrically connected to the plurality of circuit parts. At least a part of the plurality of electrode portions includes a base that is long in one axis direction.

The rigid member is disposed on the first surface, includes, at least one shaft portion, and faces the base with the dielectric layer sandwiched therebetween, the at least one shaft axis extending along the one axis direction.

The sealing layer is provided on the first surface and covers the plurality of circuit parts and the rigid member.

In the semiconductor module, since the rigid member that faces the base with the dielectric film sandwiched therebetween is provided, the mold pressure of the resin toward the base when forming the sealing layer is shut off by the rigid member. As a result, it is possible to inhibit the base from being deformed.

The dielectric film may be formed to have a rectangular shape having two sides in parallel with the one axis direction, and the rigid member may include two shaft portions that extend along the two sides of the dielectric film.

The rigid member may be formed of a frame-like member that is disposed along a periphery of the dielectric film and surrounds the plurality of circuit parts.

The rigid member may be formed of a pair of shaft-like members disposed along the two sides of the dielectric film.

The plurality of circuit parts may include a power semiconductor device, and the base may be provided in one of the plurality of electrode portions, which is to be connected to the power semiconductor device.

The dielectric film may be formed of polyimide.

The semiconductor module may further include a solder resist layer that is provided on the second surface and includes an opening that exposes the base, and the rigid member may be disposed at a position facing the opening with the dielectric film sandwiched therebetween.

The base may be a copper plating layer that has a thickness of not less than 20 μm and not more than 50 μm and a width perpendicular to the one axis direction of not less than 1 mm and not more than 2 mm.

In accordance with another embodiment of the present disclosure, there is provided a semiconductor module, including: a dielectric film; a plurality of circuit part; an electrode layer; and a rigid member.

The dielectric film has a first surface and a second surface opposed to the first surface.

The plurality of circuit parts is mounted on the first surface.

The electrode layer is disposed on the second surface and includes a plurality of electrode portions to be electrically connected to the plurality of circuit parts, at least a part of the plurality of electrode portions including a base that is long in one axis direction.

The rigid member is disposed on the first surface, includes, at least one shaft portion, and faces the base with the dielectric layer sandwiched therebetween, the at least one shaft axis extending along the one axis direction.

The rigid member may have a thickness smaller than each of the plurality of circuit parts.

As described above, in accordance with the present disclosure, it is possible to inhibit an electrode layer from being deformed to secure mounting reliability on the substrate.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a perspective view schematically showing a configuration of a semiconductor module according to an embodiment of the present disclosure;

FIG. 2 is a schematic cross-sectional view taken along the line A-A in FIG. 1;

FIG. 3 is a schematic cross-sectional view taken along the line B-B in FIG. 1;

FIG. 4 is a schematic back view of the semiconductor module on the side of an electrode layer;

FIG. 5 is an equivalent circuit diagram of main portions of the semiconductor module;

FIGS. 6A and 6B are each a schematic cross-sectional view of main portions of the electrode layer describing the operation of the semiconductor module;

FIG. 7 is a perspective view showing a modified example of the configuration of the semiconductor module;

FIG. 8 is a schematic perspective view showing another modified example of the configuration of the semiconductor module;

FIG. 9A is a schematic plan view of a semiconductor module according to an embodiment of the present disclosure on the side of the electrode layer;

FIG. 9B is a schematic cross-sectional view taken along the line C-C in FIG. 9A; and

FIG. 9C is a cross-sectional view taken along the line D-D in FIG. 9A.

### DETAILED DESCRIPTION OF EMBODIMENTS

[Overview]

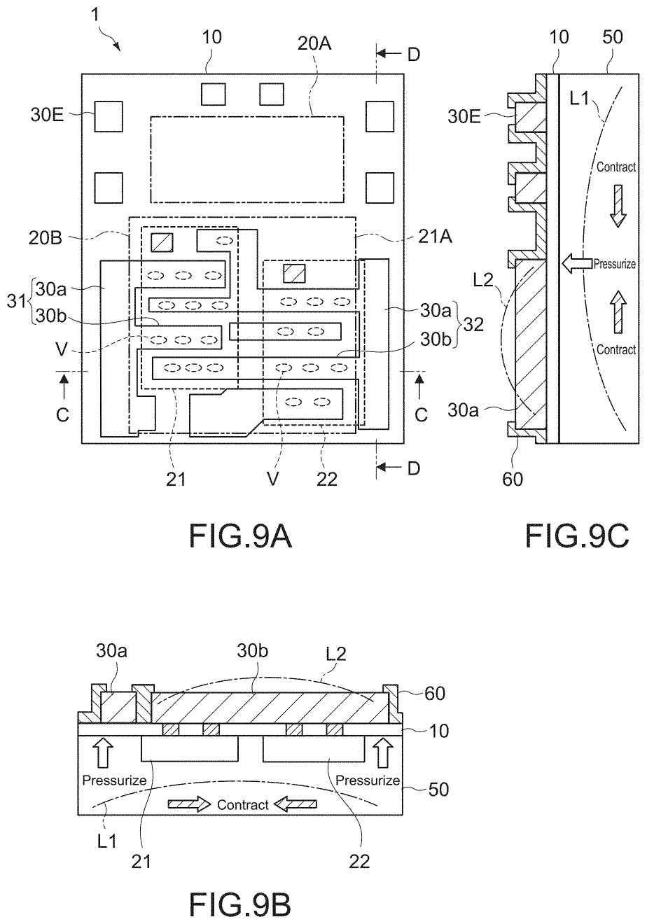

First, an overview of a semiconductor module according to an embodiment of the present disclosure will be described with reference to FIGS. 9A to 9C. FIG. 9A is a schematic plan view of a semiconductor module 1 on the side of an electrode layer, FIG. 9B is a schematic cross-sectional view taken along the line C-C in FIG. 9A, and FIG. 9C is a schematic cross-sectional view taken along the line D-D in FIG. 9A.

A reference symbol 10 indicates a dielectric film 10 formed of polyimide. The polyimide film is a substrate that is formed of a material having an excellent high-temperature and high-withstand-voltage characteristics and has a small thickness of approximately 25 μm and flexibility. A conductive pattern including a Cu (copper) plating layer having a thickness of approximately 50 μm is formed on at least the surface side (front side surface in FIG. 9A) of the dielectric film 10. A large current and high temperature are handled, and thus, the conductive pattern is formed to have a low resistance and to be thick considering as a heat sink or heat dissipation characteristics. The conductive pattern includes an electrode, a wire, and the like.

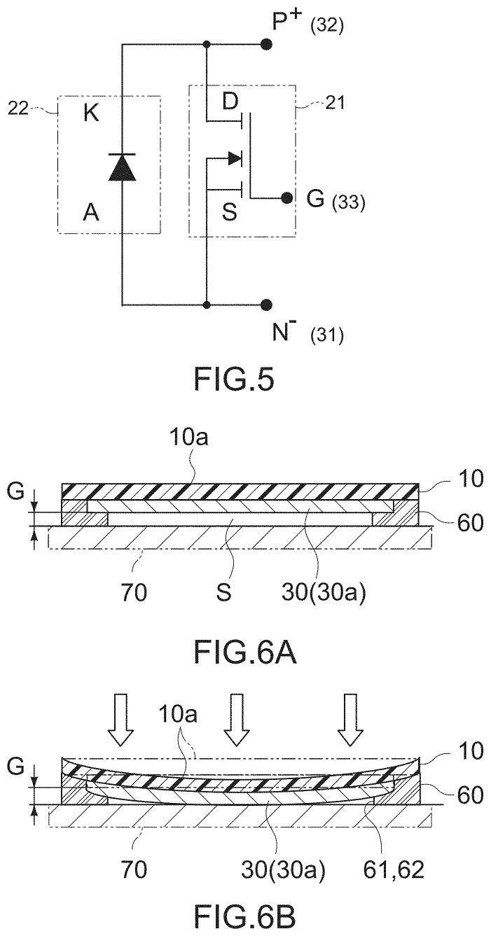

With reference to FIG. 9A, a reference symbol 20A shown by a rectangular dotted line indicates a control area (one region of the substrate), and a reference symbol 21A indicates a switching area (the other region of the substrate). Although not shown in detail in the control area 20A, for example a control IC is mounted facedown on the back side (back side surface in FIG. 9A) of the dielectric film 10. On the front side of the dielectric film 10, wires are radially provided from the arrangement region of the control IC, and electrodes 30E are provided at the tips thereof. Further, in the switching area 21A, switching devices or diodes 21 and 22 indicated by a rectangular broken line are provided on the back side of the dielectric film 10. For example, a power transistor 21 and a protective diode 22 shown in FIG. 5 are provided, and are respectively connected to electrode portions 31 and 32 provided on the front side of the dielectric film 10. Further, the devices shown by two rectangles may each be a power transistor. For example, the devices may be a circuit obtained by connecting two transistors in series, such as a three-phase invertor circuit and a push-pull structure.

The power transistor 21 is provided on a comb-tooth portion 30b of the electrode 31, and the source electrode, drain electrode, and gate electrode thereof are electrically connected to the comb-tooth portion 30b via a via V. A base 30a that is an electrode for collecting the comb-tooth portions 30b is provided at a position adjacent to the arrangement region of the transistor.

Note that although not specifically shown, a plurality of passive parts such as a chip resistor and a chip capacitor is provided on the back side of the dielectric film 10. Further, a solder resist layer (PSR) 60 having a size of approximately 60 to 80 μm covers the entire front side of the dielectric film 10 (FIG. 9B and 9C) so that the portion to be an electrode of the conductive pattern is exposed. For example, solder or the like is provided on the electrode portion exposed from the solder resist layer 60 for mounting on a mother board.

Note that although described below, the conductive pattern including the electrodes 30E, 31, and 32 is electrically connected to the electrode of the IC or transistor via a via (hole) formed in the dielectric film 10.

Meanwhile, as shown in FIG. 9B or FIG. 9C, a sealing layer 50 that protects the plurality of circuit parts including passive devices such as the IC, the switching devices 21 and 22, and the chip capacitor is provided on the back side of the dielectric film 10. The thickness of the sealing layer 50 is regulated by the thickest part, e.g., chip capacitor, and have a resin thickness of approximately 1 mm to 2 mm. Further, the sealing layer 50 is formed of an epoxy resin, and is generally provided by vacuum printing, compression molding, or transfer molding. Hereinafter, the above is organized focusing on the size (example).

Thickness of dielectric film 10: 20 μm to 50 μm

Thickness of solder resist layer: 60 μm to 80 μm

Resin thickness of sealing layer 50: 1 mm to 2 mm (1000 μm to 2000 μm)

Thickness of conductive pattern (electrode and wire): 50 μm to 100 μm

Width of base 30a: 1.2 mm (1200 μm)

Width of comb-tooth portion 30b: 0.8 mm (800 μm)

Width of another conductive pattern: approximately 0.3 mm (300 μm)

In a generally used glass epoxy substrate, a conductive pattern is generally thinner than a substrate. However, as described above, a film having a thickness similar to that of the conductive pattern or smaller than the conductive pattern is used, and a sealing resin having a size approximately 100 times the thickness of the thin dielectric film or the thickness of the conductive pattern is provided. On the basis of such a relationship, the semiconductor module according to this embodiment is completely different from a general substrate module including a glass epoxy substrate in the mechanical characteristics, the degree of generation of stress, and the like.

Note that since the sealing layer 50 having a thickness of 1 mm to 2 mm is provided on the back side of the dielectric film 10 having a thickness of 25 μm, a warp occurs in the entire film as shown by a line L1 in FIG. 9B and 9C due to cure shrinkage of the sealing layer 50.

Further analysis has revealed that when injecting a resin, a warp of the electrode shown by a line L2 in FIG. 9B and 9C occurs due to the injection pressure. This is because the solder resist layer 60 is in contact with the bottom surface of the mold, and the pressure at the time of sealing is applied from the back side of the dielectric film to the front side. In particular, in the case of an electrode having a wide width of 1.2 mm (particularly, the base), a remarkable warp of the electrode occurs in the width direction or the longitudinal direction. Note that a warp is unlikely to occur in the comb-tooth portion 30b because the film and chip are fixed via an adhesive in the portion of the switching area where the transistor is disposed. Meanwhile, in the case of the electrode of the base 30a having a wide width where no transistor is disposed, a warp as shown by the line L2 is likely to occur due to the wide width.

That is, it has been found that the electrode portion where the circuit part or semiconductor device is fixed is flat to some extent due to the rigidity of the part or semiconductor device, but a warp occurs over the entire substrate due to the sealing resin as described above as well as a warp occurs in the portion of the base 30a having a wide width because no rigid object is provided. Further, in the case of a module in which the sealing layer 50 is not provided, a film having a size of 20 μm to 50 μm and a conductive pattern having a size of 20 μm to 50 μm are formed in the same range, but a warp occurs due to the difference in thermal expansion coefficient between the metal and resin. In addition, the boundary between the switching area 21A and the control area 20A is a boundary (space) between two rigid areas, where a phenomenon of bending with the boundary as a base line occurs due to heat by the reflow when mounting on the motherboard.

In any case, the warp of the entire substrate causes solder defects when mounting on the motherboard. Further, it has been found that the warp of the base 30a occurs in the vicinity of the via V of the comb-tooth portion 30b located in the vicinity of the base, and a defect such as peeling of the contact portion of the via V occurs due to the warp. Further, it has been found that there is a problem that a resistance value increases due to the warp of the electrode, the switching speed decreases, and the temperature rises, and it is necessary to consider the problem as a whole.

Hereinafter, this embodiment will be described in detail.

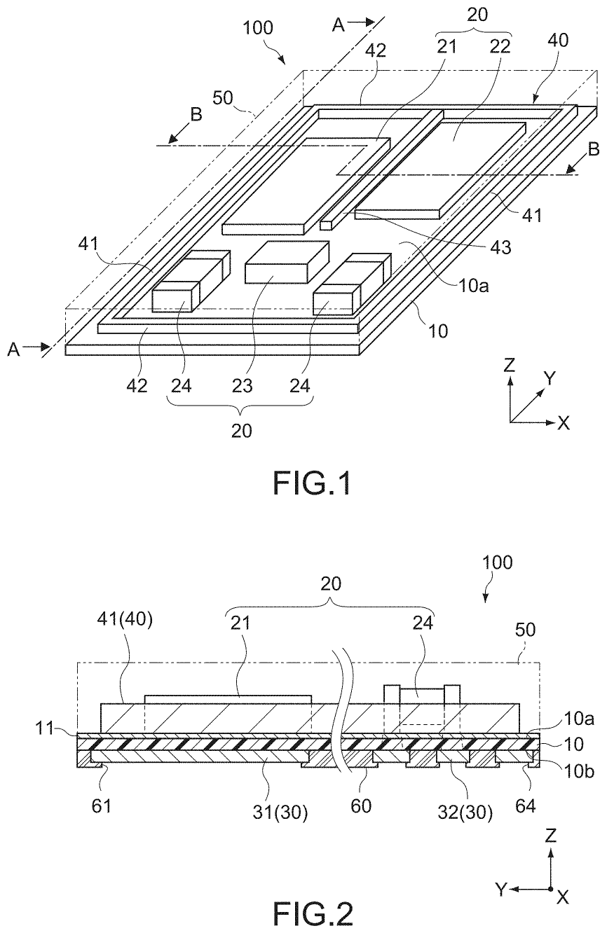

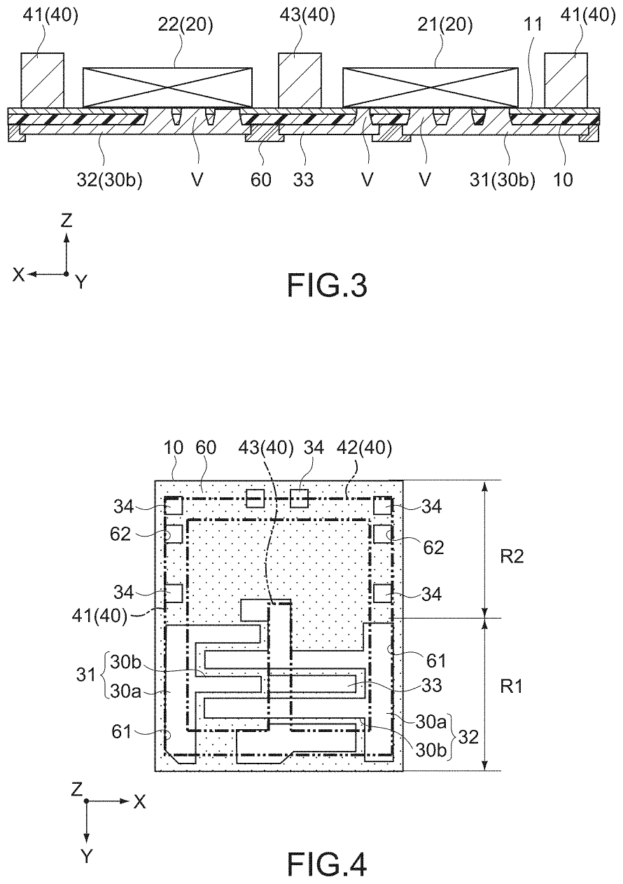

FIG. 1 is a perspective view schematically showing the configuration of a semiconductor module 100 according to an embodiment of the present disclosure, FIG. 2 is a schematic cross-sectional view taken along the line A-A in FIG. 1, FIG. 3 is a schematic cross-sectional view taken along the line B-B in FIG. 1, and FIG. 4 is a schematic back view of the semiconductor module 100. In each figure, the X axis, Y axis, and Z axis represent three axis directions orthogonal to each other, the X axis and Y axis correspond to the in-plane direction of the semiconductor module 100, and the Z axis corresponds to the thickness direction of the semiconductor module 100. Note that FIG. 1 is obtained by reversing the front and back of FIGS. 9A to 9C and rotating the paper by 180 degrees.

The semiconductor module 100 includes the dielectric film 10, a circuit part 20, an electrode layer 30, a rigid member 40, and the sealing layer 50. The rigid member 40 includes, for example, a frame or a plate having a rectangular, semicircular, semielliptical, or triangular cross section.

[Dielectric Film]

The dielectric film 10 is formed of an electrically insulating resin material having a predetermined thickness. In this embodiment, the dielectric film 10 includes a polyimide film having a thickness of 25 μm. Polyimide is very advantageous from the viewpoints of processability, insulation withstand voltage characteristics, chemical resistance, and the like.

The present disclosure is not limited thereto, and the thickness of the dielectric film 10 can be appropriately set in accordance with the dielectric constant of the material, the magnitude of the insulation withstand voltage, or the like. For example, the thickness of the dielectric film 10 is appropriately selected within the range of approximately not more than 20 μm and not less than 50 μm. The dielectric material is also not limited to polyimide. For example, an appropriate material such as polytetrafluoroethylene (PTFE), polysulfone, and a liquid crystal polymer can be adopted, and these materials have flexibility.

The shape of the dielectric film 10 is also not particularly limited, and the dielectric film 10 is typically formed in a rectangular shape. The size of the plane of the dielectric film 10 is also not particularly limited. In this embodiment, the dielectric film 10 has a long side parallel to the Y-axis direction of not less than 10 mm and not more than 20 mm and a short side parallel to the X-axis direction of not less than 5 mm and not more than 15 mm.

The dielectric film 10 has a first surface 10a (back side surface in FIG. 9A) and a second surface 10b (front side surface in FIG. 9B) opposed to the first surface 10a. A plurality of the circuit parts 20 is mounted on the first surface 10a via an adhesive layer 11, and the electrode layer 30 to be electrically connected to the plurality of circuit parts 20 is disposed on the second surface 10b via the dielectric film 10.

The adhesive layer 11 includes a liquid or fluid adhesive or a film-like adhesive sheet applied to the first surface 10a. The type of the adhesive layer 11 is not particularly limited. The adhesive layer 11 is formed of an appropriate insulating resin material such as an epoxy resin material and an acrylic resin material. The thickness of the adhesive layer 11 is not particularly limited, and is, for example, 15 μm. Further, the adhesive layer 11 has heat resistance in consideration of the temperature rise during driving. Note that the adhesive may be provide on the entire surface, or selectively provided on the area in which circuit parts are mounted.

[Circuit Part]

The plurality of circuit parts 20 are mounted on the adhesive layer 11 on the first surface 10a of the dielectric film 10. The plurality of circuit parts 20 typically includes active parts such as semiconductor devices. As the semiconductor devices, a control IC and a discrete power switching device, e.g., transistor are used. In this embodiment, the semiconductor devices include the power transistor 21 and the diode 22 through which a large current flows. The semiconductor devices further include a control IC 23 that controls the power transistor 21. The circuit parts 20 further include passive parts 24 such as a capacitor and a resistor. A predetermined circuit part among the circuit parts 20 is electrically connected to the electrode layer 30.

The power transistor 21 includes a BiP transistor, MOSFET, IGBT, or the like formed of Si, or a transistor formed of SiC, GaN, or the like. These semiconductor devices include a bare chip, and are mounted in a so-called facedown manner with the active surface facing the first surface 10a. A heat sink for heat radiation may be bonded to the inactive surface (upper surface in the figure) of each of the power transistor 21 and the power diode 22 via a bonding material such as solder. The heat sink is formed of Cu or Al as a main material, and may include a metal plate or a thick metal/alloy film by plating or sputtering. Further, a substrate called DBC (DBA) obtained by bonding Cu to a ceramic substrate may be bonded for heat radiation. Note that the transistor does not necessarily need to be a bare chip, and may be a sealing transistor such as a chip size package or resin sealing package.

[Electrode Layer]

The electrode layer 30 is disposed on the second surface 10b of the dielectric film 10, and typically includes a metal plating layer formed on the second surface 10b. As the metal plating layer, typically, a plating layer formed of a material containing copper (Cu) as a main material is adopted. The electrode layer 30 includes the via V (see FIG. 3) as an interlayer connection portion to be electrically connected to each of the circuit parts 20 via the dielectric film 10.

When forming the electrode layer 30, first, laser light is applied from the side of the second surface 10b to the electrode terminal of each of the circuit parts 20 mounted on the first surface 10a of the dielectric film 10. As a result, the dielectric film 10 and the adhesive layer 11 are drilled, and each electrode terminal is exposed to the side of the second surface 10b. Subsequently, a conductor layer to be a seed layer is formed on the second surface 10b by a sputtering method, and then, a copper plating layer having a predetermined thickness is formed by an electrolytic plating method. As a result, the electrode layer 30 including the via V is formed, and the electrode layer 30 and the circuit part 20 are electrically connected to each other.

For the formation of the conductor layer to be a seed layer, the sputtering method does not necessarily need to be adopted, and an electroless plating method may be adopted. The thickness (thickness from the second surface 10b) of the electrode layer 30 is not particularly limited, and is, for example, not less than approximately 50 μm and not more than 100 μm. As a result, the current characteristics of the electrode layer 30 and productivity can be secured. Further, the thicker the electrode layer, the larger the current that can be handled and the better the heat dissipation. Therefore, in this embodiment, the electrode layer 30 is caused to function as the heat sink for the heat generated from the circuit part and as the heat radiation electrode. Note that since the electrode is formed of Cu, at least one anti-oxidation film formed of, for example, Ni, Ni/Au, or Ni/Pd/Au is provided on the surface.

For the plating, there are two method, i.e., a method of forming plating on the entire dielectric film 10 and then patterning it, and a method of forming a plating resist on the dielectric film 10 and selectively covering the film.

The former is used here, and the electrode layer 30 is patterned into a plurality of electrode portions having a predetermined shape by using a photolithographic technology. As shown in FIG. 4, the electrode layer 30 includes a first electrode portion 31 and a second electrode portion 32 that face each other in the X-axis direction and each have a comb shape, a third electrode portion 33 that is disposed between the first and second electrode portions 31 and 32 and long in the Y-axis direction, and a plurality of fourth electrode portions 34. Note that in FIG. 4, the first and second electrode portions 31 and 32 each include the comb-tooth portion 30b and the base 30a.

The first electrode portion 31 is connected to a source terminal (S) of the power transistor 21 and an anode terminal (A) of the power diode 22. The second electrode portion 32 is connected to a drain terminal (D) of the power transistor 21 and a cathode terminal (K) of and the power diode 22. The third electrode portion 33 is connected to a gate terminal (G) of the power transistor 21. The fourth electrode portions 34 are connected to respective terminal portions of the control IC 23 and the passive parts 24. FIG. 5 is an equivalent circuit diagram of main portions of the semiconductor module 100.

Note that the circuit shown in FIG. 5 is an example. As another example, also a circuit in which two power transistors are connected in series, which is adopted in an inverter circuit, is conceivable. In this case, reference symbols 21 and 22 each indicate a power transistor. In any case, the second mounting region on which this transistor is mounted is a portion where a large current flows and high heat is generated.

The electrode layer 30 is provided to be divided into a region R1 and a region R2. The region R1 is a switching area in which first to the third electrode portions 31 to 33 are formed. The region R2 is a control area in which a conductive pattern to be connected to the fourth electrode portions 34 and the control IC 23 is formed. Although illustration is omitted, the above-mentioned conductive pattern is disposed radially from the lower side of the control IC 23, for example.

As shown in FIG. 4, the region R1 and the region R2 correspond to respective regions obtained by dividing the dielectric film 10 into two in the long side direction. In the illustrate example, the areas of the regions are set to be approximately equal to each other, or the area of the region R1 is set to be slightly larger than that of the region R2.

The first electrode portion 31 and the second electrode portion 32 each include the base 30a that extends in a band shape in parallel to the Y-axis direction, and a plurality of the comb-tooth portions 30b that extends from a base 30a in parallel to the X-axis direction. The bases 30a are each formed to have a width wider than the comb-tooth portion 30b, and the width is, for example, not less than 1 mm and not more than 2 mm. The bases 30a are disposed at the periphery of the dielectric film 10, typically, along two long sides. For example, in the case where a current flows from the comb-tooth portion 30b to the base 30a, the current is collected in the base 30a. In this regard, the width of the base 30a is caused to increase.

The semiconductor module 100 further includes the solder resist layer 60 (in FIG. 4, the region in which the solder resist layer 60 is formed is shown by dots). The solder resist layer 60 is provided on the second surface 10b of the dielectric film 10, and includes a first opening 61 and a second opening 62. The first opening 61 opens a predetermined region of the electrode layer 30.

The first opening 61 causes the electrode layer 30 (first to third electrode portions 31 to 33) located in the region R1 to be partially exposed. The second opening 62 causes the electrode layer 30 (the fourth electrode portions 34) located in the region R2 to be partially exposed. The regions of the electrode portions 31 to 34 exposed via the first and second openings 61 and 62 are each configured as an external connection terminal to be connected to an external substrate (motherboard) (not shown).

In this embodiment, the first opening 61 is formed along the periphery of the first to third electrode portions 31 to 33. As a result, it is possible to secure the opening area of the first to third electrode portions 31 to 33, and cope with a large current as an external connection terminal. Meanwhile, the fourth electrode portions 34 are formed as normal signal terminals, and the second opening 62 is formed in a rectangular island shape having an area smaller than the first opening 61. The second openings 62 are formed at predetermined intervals in the long side direction (Y-axis direction) and the upper side direction (X-axis direction) of the region R2 of the dielectric film 10 so as to be aligned with the bases 30a of the first and second electrode portions 31 and 32.

[Sealing Layer]

The sealing layer 50 is provided on the first surface 10a of the dielectric film 10 so as to cover the plurality of circuit parts 20. The sealing layer 50 is typically formed of an epoxy synthetic resin material, and inhibits the outside air containing moisture and the like from coming into contact with the circuit part 20.

The method of forming the sealing layer 50 is not particularly limited. Typically, a molding method such as a compression molding method and a transfer molding method is adopted. The compression molding method is a method of overlaying the upper mold on the lower mold, and sinking circuit parts into a resin for pressing and curing. The first surface 10a of the dielectric film 10 on which the circuit part 20 is mounted is placed facing downward in the upper mold. The lower mold has a cavity for housing a molten resin. Meanwhile, the transfer molding method is a method of overlaying the upper mold on the lower mold, and filling a cavity with a molten resin by pushing the molten resin using a plunger. The first surface 10a of the dielectric film 10 on which the circuit part 20 is mounted is placed facing upward in the lower mold. The cavity is formed between the upper mold and the lower mold via a runner and a gate.

In the case of adopting either of the compression molding method and the transfer molding method, the dielectric film 10 receives the pressure of a resin from the side of the first surface 10a to the side of the second surface 10b at the time of pressurization. The dielectric film 10 is as thin as approximately 25 μm, and has flexibility. In the region of the first surface 10a in which the circuit part 20 is mounted, the pressure to be transmitted to the side of the second surface 10b is small because the circuit part receives the pressure of the filling resin. Meanwhile, in the region in which the circuit part 20 is not mounted, the pressure of the filling resin is transmitted also to the electrode layer 30 on the side of the second surface 10b because the region directly receives the pressure of the filling resin.

In particular, the solder resist layer 60 having a thickness of 60 μm to 80 μm, which is thicker than the film, is provided on the second surface 10b, and the opening 61 and 62 that partially expose a predetermined region of the electrode layer 30 (first to fourth electrode portions 31 to 34) are provided in the solder resist layer 60. As shown in FIG. 6A, the openings 61 and 62 each have a step having a predetermined depth (height) G between the electrode layer 30 and the solder resist layer 60. Therefore, when setting the side of the electrode layer 30 of the dielectric film 10 on the surface of a flat-plate molding jig (lower mold) 70 at the time of forming the sealing layer 50, a space layer S having a thickness corresponding to the step G is formed between the electrode layer 30 to be exposed via the openings 61 and 62, and the molding jig 70.

The space layer S intervenes between the electrode layer 30 and the molding jig 70 at the portion, which corresponds to the region in which the circuit part 20 is not mounted, of the openings 61 and 62. For this reason, as schematically shown in FIG. 6B, when the resin filling pressure is applied to the first surface 10a, the dielectric film 10 and the electrode layer 30 are deformed to protrude toward the molding jig 70 in some cases. The amount of deformation depends on the opening width of the openings 61 and 62, the thickness of the electrode layer 30, and the like, and reaches the size corresponding to the thickness of the space layer S (depth G of the openings 61 and 62) at most. As a result, the flatness of the electrode layer 30 is reduced, and the height of the electrode layer 30 varies between the mounting region and the non-mounting region of the circuit part 20, resulting in loss of the mounting reliability on the external substrate (motherboard).

This causes a warp over the entire dielectric film 10 and a warp of the electrode layer 30 itself to occur, and solder is not attached in the solder connection to the motherboard in some cases. Further, particularly, the base 30a is warped due to the warp of the electrode, which applies a load to the via in the vicinity of the base 30a. Thus, a problem also occurs in the connectivity between the transistor and the electrode.

In order to solve such a problem, the semiconductor module 100 according to this embodiment includes the rigid member 40 for inhibiting the dielectric film 10 and the electrode layer 30 from being deformed. Hereinafter, the rigid member 40 will be described in detail.

[Rigid Member]

The rigid member 40 is disposed on the first surface 10a of the dielectric film 10, which is the placement surface of the sealing layer 50, so as to face the electrode layer 30 with the dielectric film 10 sandwiched therebetween. As shown in FIG. 1, the rigid member 40 is disposed in the region in which the circuit part 20 is not mounted of the first surface 10a. In this embodiment, the rigid member 40 is formed of a frame-like member disposed around the dielectric film 10 so as to surround the plurality of circuit parts 20. The rigid member 40 is bonded to the dielectric film 10 via the adhesive layer 11, similarly to the circuit part 20.

The rigid member 40 includes a pair of first shaft portions 41 and a pair of second shaft portions 42. The pair of first shaft portions 41 extends along two long sides of the dielectric film 10. The pair of second shaft portions 42 extends along two short sides of the dielectric film 10. The pair of first shaft portions 41 is arranged at a position corresponding to the corresponding base 30a of the first and second electrode portions 31 and 32 exposed via the opening 61 of the solder resist layer 60 of the electrode layer 30. That is, the first shaft portions 41 are arranged at positions facing the corresponding bases 30a with the dielectric film 10 sandwiched therebetween (see FIG. 2).

The rigid member 40 has rigidity to such an extent that deformation of the dielectric film 10 and deformation of the base 30a do not occur even when receiving the resin filling pressure in the process of forming the sealing layer 50. The material forming the rigid member 40 is not particularly limited, and may be a conductor or non-conductor. As the conductor, typically, the rigid member 40 is formed of a metal material. As a result, it is possible to form a heat radiation path of the semiconductor module 100.

If the rigid member 40 is formed of a metal, in the case of FIG. 1, considering the short circuit of the transistor and the electrode around the IC, an insulating material is provided on the adhesive surface of the rigid member 40 or the rigid member 40 is disposed in a ring shape so as to surround the dielectric film 10 and be separated into several portions, thereby inhibiting the short circuit from occurring. In particular, the rigid member 40 may be disposed only on the portions corresponding to two bases 30a each having a large warp. Meanwhile, if the rigid member 40 is formed of an insulating material containing ceramic or a resin, the short circuit can be ignored, and thus, the rigid member 40 is provided in a ring shape as shown in FIG. 1.

Further, when mounting the transistor and the like, the rigid member 40 is also mounted. Therefore, at least a part of the surface of the rigid member 40 is favorably flat. This is because vacuum suction is made possible.

The metal material forming the rigid member 40 is not particularly limited, and a material having a high thermal conductivity and a small thermal expansion coefficient is favorable. As the material of the rigid member 40, a high hardness/melting-point material such as tungsten (W) and molybdenum (Mo) may be adopted. As a result, it is possible to easily secure desired rigidity. Meanwhile, as the non-conductor, a ceramic material such as alumina and glass is favorable.

The width of each of the first and second shaft portions 41 and 42 is not particularly limited, but is favorably larger than the opening 61 (opening width) of the solder resist layer 60. As a result, it is possible to inhibit, when forming the sealing layer 50, the resin filling pressure from being transmitted to the base 30a in the opening 61. Therefore, it is possible to effectively inhibit the base 30a from being deformed. Further, it is possible to maintain the flatness of the rigid member 40 because both ends of the pair of first shaft portions 41 are connected by the pair of second shaft portions 42.

Also the height (thickness) of each of the first and second shaft portions 41 and 42 is not particularly limited, and is set to an appropriate value that can ensure the rigidity necessary for the rigid member 40. The height of each of the first and second shaft portions 41 and 42 may be larger or smaller than the height of the circuit part 20. The first and second shaft portions 41 and 42 are each formed to have the same thickness, but the first shaft portion 41 facing the base 30a may be formed to be thicker than the second shaft portion 42. Also the cross-sectional shape of each of the first and second shaft portions 41 and 42 is not particularly limited. The cross-sectional shape is typically a rectangular shape, but may be a triangular shape, a hemispherical shape, or the like with the side of the dielectric film 10 as the bottom.

Note that considering mounting by vacuum suction, the flatness of the dielectric film 10 is maintained by providing the rigid member 40 before mounting the circuit part 20. Therefore, considering that the circuit part 20 is to be mounted later, in the case where the thickness of the rigid member 40 is smaller than that of the circuit part 20, the portion of the suction head does not hit.

The rigid member 40 according to this embodiment further includes a third shaft portion 43 disposed between the power transistor 21 and the power diode 22 in accordance with the circuit configuration (see FIG. 1 and FIG. 3). The third shaft portion 43 is formed in parallel with the first shaft portions 41 to have a length shorter than the first shaft portions 41, and one end of the third shaft portion 43 is integrally connected to one of the second shaft portions 42. Since the third shaft portion 43 is disposed between the two power semiconductor devices, the heat dissipation of each device is improved. Further, it is also possible to inhibit the electrode layer located between the two devices from being deformed.

The rigid member 40 may be covered by the sealing layer 50 after being disposed on the first surface 10a of the dielectric film 10 together with the circuit part 20. Since the first shaft portions 41 of the rigid member 40 is disposed at a position facing the base 30a of the electrode layer 30 with the dielectric film 10 sandwiched therebetween, the rigid member 40 receives the resin filling pressure in the step of forming the sealing layer 50, and thus, the resin filling pressure is inhibited from being transmitted to the base 30a. Further, the base 30a and the third electrode portion 34 aligned in the longitudinal direction are blocked from each other by the rigid member 40 (the first shaft portions 41). As a result, it is possible to inhibit the electrode layer 30 exposed from the respective openings 61 and 62 of the solder resist layer 60 from being deformed.

Further, since the rigid member 40 is formed of a frame-like member disposed along the periphery of the dielectric film 10, the first and second shaft portions 41 and 42 are disposed so as to straddle the region R1 and the region R2 of the dielectric film 10. As a result, also the flatness of the entire dielectric film 10 is secured, and it is also possible to suppress a warp of the dielectric film 10. Further, it is also possible to suppress a warp of the dielectric film 10 due to the large or small size of the electrode layer 30 or the large or small mounting density of the circuit part 20. Further, it is also possible to improve the strength or rigidity of the semiconductor module 100, and further improve the mounting reliability by effectively suppressing a warp of the semiconductor module 100 at the time of reflow mounting to the external substrate (motherboard). Further, even in a module in which the sealing layer 50 is omitted, it is possible to suppress a warp of the entire dielectric film 10, and improve the mountability on the motherboard.

As described above, in accordance with this embodiment, even in the case where the electrode area is increased to secure desired large current characteristics, it is possible to effectively inhibit the electrode layer from being deformed and the height position of the electrode surface from varying. Further, even in the case where an extremely thin dielectric film 10 is adopted as the support substrate of the circuit part 20, it is possible to suppress a warp of the semiconductor module 100. As a result, it is possible to secure the mounting reliability of the semiconductor module 100. Further, an unnecessary load is not applied to the contact located in the vicinity of the base 30a, specifically, the contact portion between the comb-tooth portion 30b and the transistor 21, and a favorable contact can be maintained.

Although an embodiment of the present disclosure has been described above, the present disclosure is not limited to the above-mentioned embodiment and various modifications can be made without departing from the essence of the present technology.

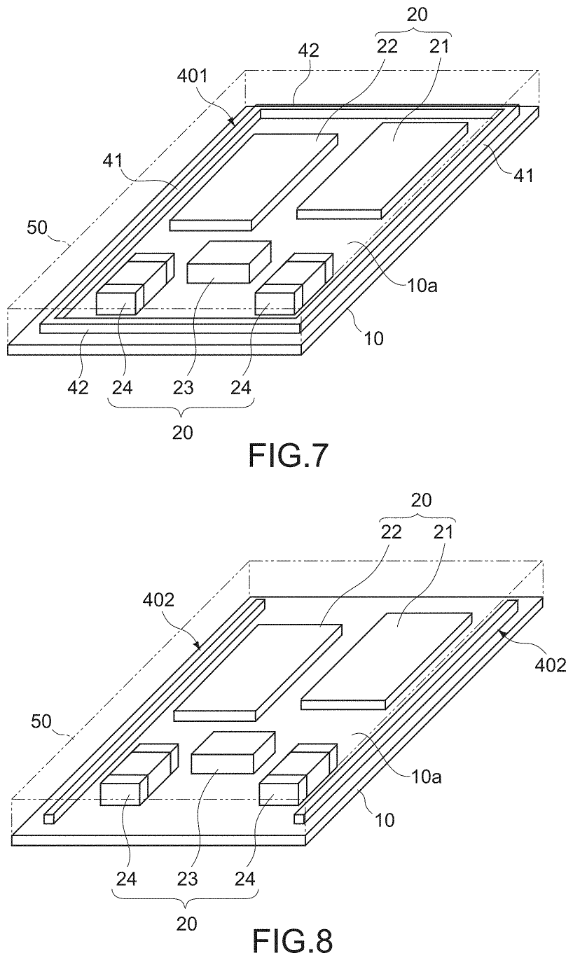

For example, although the rigid member 40 has been formed of a frame-like member including the first to third shaft portions 41 to 43 in the above-mentioned embodiment, the present disclosure is not limited thereto, and the rigid member 40 may be configured as shown in FIG. 7 or FIG. 8.

FIG. 7 shows an example in which a rigid member 401 is formed of a frame-like member in which the third shaft portion 43 is omitted. Also with such a configuration, it is possible to achieve the operation and effect similar to those in the above-mentioned embodiment.

FIG. 8 shows an example in which a rigid member 402 is formed of a pair of shaft-like member. Each shaft-like member is disposed along the long side direction of the dielectric film 10, and disposed at a position facing the base 30a of the electrode layer 30 similarly to the above-mentioned embodiment. Also with such a configuration, it is possible to achieve the operation and effect similar to those in the above-mentioned embodiment. In any case, it is favorable to dispose the rigid member so as to straddle the control area 20A and the switching area 21A and to be superimposed on at least the right and left bases 30a.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor module, comprising:
a dielectric film that has a first surface and a second surface opposed to the first surface;
a plurality of circuit parts mounted on the first surface;
an electrode layer that is disposed on the second surface and includes a plurality of electrode portions to be electrically connected to the plurality of circuit parts, at least a part of the plurality of electrode portions including a base that is long in one axis direction;
a rigid member that is disposed on the first surface, includes, at least one shaft portion, and faces the base with the dielectric layer sandwiched therebetween, the at least one shaft axis extending along the one axis direction; and
a sealing layer that is provided on the first surface and covers the plurality of circuit parts and the rigid member.

2. The semiconductor module according to claim 1, wherein
the dielectric film is formed to have a rectangular shape having two sides in parallel with the one axis direction, and
the rigid member includes two shaft portions that extend along the two sides of the dielectric film.

3. The semiconductor module according to claim 2, wherein
the rigid member is formed of a frame-like member that is disposed along a periphery of the dielectric film and surrounds the plurality of circuit parts.

4. The semiconductor module according to claim 2, wherein
the rigid member is formed of a pair of shaft-like members disposed along the two sides of the dielectric film.

5. The semiconductor module according to claim 1, wherein
the plurality of circuit parts include a power semiconductor device, and
the base is provided in one of the plurality of electrode portions, which is to be connected to the power semiconductor device.

6. The semiconductor module according to claim 1, wherein
the dielectric film is formed of polyimide.

7. The semiconductor module according to claim 1, further comprising
a solder resist layer that is provided on the second surface and includes an opening that exposes the base,
the rigid member being disposed at a position facing the opening with the dielectric film sandwiched therebetween.

8. The semiconductor module according to claim 1, wherein
the base is a copper plating layer that has a thickness of not less than 20 μm and not more than 50 μm and a width perpendicular to the one axis direction of not less than 1 mm and not more than 2 mm.

9. The semiconductor module according to claim 1, wherein the rigid member has a thickness smaller than each of the plurality of circuit parts.

10. A semiconductor module, comprising:
a dielectric film that has a first surface and a second surface opposed to the first surface;
a plurality of circuit parts mounted on the first surface;
an electrode layer that is disposed on the second surface and includes a plurality of electrode portions to be electrically connected to the plurality of circuit parts, at least a part of the plurality of electrode portions including a base that is long in one axis direction; and
a rigid member that is disposed on the first surface, includes, at least one shaft portion, and faces the base with the dielectric layer sandwiched therebetween, the at least one shaft axis extending along the one axis direction.

11. The semiconductor module according to claim 10, wherein
the rigid member has a thickness smaller than each of the plurality of circuit parts.
